(19) United States
(12) Patent Application Publication
(10) Pub. No.: US 2018/0351525 A1
(43) Pub. Date: Dec. 6, 2018

(54) VIDEO OR AUDIO PROCESSING FORMING AN ESTIMATED QUANTILE

(71) Applicant: Snell Advanced Media Limited, Newbury (GB)

(72) Inventor: Michael James Knee, Petersfield (GB)

(21) Appl. No.: 16/058,842

(22) Filed: Aug. 8, 2018

Related U.S. Application Data
(63) Continuation-in-part of application No. 13/950,469, filed on Jul. 25, 2013, now abandoned.

(30) Foreign Application Priority Data
Jul. 26, 2012 (GB) 1213358.3

(51) Int. Cl. H03G 3/32; H03G 5/16; H04S 7/00

(52) U.S. Cl. CPC H03G 3/32; H04S 7/301; H03G 5/165

(57) ABSTRACT

A method of audio processing receives a sequence of sample values, each corresponding with a location in video or audio content; forms an initially estimated quantile value; and then modifies the estimated value in dependence upon a count of the results of comparisons between sample values within a fixed-length interval of the sequence of samples values and the estimated value to form an estimated quantile of the sequence of sample values. The estimated quantile is used in the measurement or control of loudness.

### FIELD OF INVENTION

This invention concerns audio processing and the measurement or correction of loudness.

### BACKGROUND OF THE INVENTION

A known problem in audio processing is the measurement and/or control of loudness. There are a variety of standardised loudness measurements, a number of which involve integration of loudness levels over time. In a case where the integration period spans an abrupt jump in level—for example at a cut in video content or at a transition between programme and advertising, erroneous or misleading measurements can arise. Knowledge of jumps is also vital for loudness correction. To distinguish such jumps in loudness level from natural variations, it would be helpful to have statistical measures of the variation of loudness level over time. To be effective, those statistics should be measured over a time period spanning the change in level or—where this is not possible—should represent a reasonable and reproducible estimate of such statistics.

For example, a change in level might be indicated as a jump if it were greater than a given percentage of the level changes in the period. In a theoretical situation in which past and future information were available and processing resource were unlimited, it would be possible to measure the change in level (or activity) at all samples; store those activity levels; and measure in a known manner the upper percentile of the activity level.

The upper percentile is or course a well understood statistical measure. More generally, if data is numerical or, more generally, is taken from an ordered set of possibilities, then a useful measurement that can be taken is a quantile, of which the median is the simplest example. The median is a form of average and is the data point that is halfway along an ordered set of data, or, in terms of frequency distribution, the point at which the cumulative frequency equals 0.5. Other examples of quantiles in frequent use include the lower and upper quartiles (at which the cumulative frequency equals 0.25 and 0.75 respectively), the lower and upper deciles (0.1 and 0.9) and the 1^{st} and 99^{th} centiles or percentiles (0.01 and 0.99). In this Specification, the term quantile fraction is used to refer to a specified fractional point in the distribution (for example 0.25, 0,75, 0.1, 0.9 etc.). The remainder after subtracting the quantile fraction from unity will be termed the complement of the quantile fraction. And the term quantile is used to refer to the quantity being estimated from the data.

The inventor has recognized that prior art quantile estimation methods may be reasonably accurate but require fairly complex processing. They are not suited to the above application where the accuracy required of the quantile determination may not be particularly high, but the availability of time, memory and processing capacity may be severely restricted. It is an object of one aspect of this invention to provide a method of quantile estimation for loudness measure or correction, in a simple manner with minimal memory requirements, but which is also appropriately responsive to changes in statistics. It is an object of a further aspect of this invention to provide apparatus for measuring or correcting loudness of audio content with quantile estimation functionality that is extremely simple and has minimal memory requirements, but which is also responsive to changes in statistics.

### SUMMARY OF THE INVENTION

In one aspect there is provided a method of measuring or correcting loudness in audio content, the method comprising the steps in one or more processors of: receiving a sequence of sample values derived from the audio content, forming an initially estimated quantile value; modifying the initially estimated quantile value in dependence upon a count of the results of comparisons between sample values within a fixed-length interval of the said sequence of samples values and the said initially estimated quantile value to form an estimated quantile of the sequence of sample values; and using the estimated quantile of the sequence of sample values in the measurement or correction of loudness.

The modification may be proportional to the difference between: the product of the quantile fraction and the number of samples that exceed the estimated quantile value; and the product of the complement of the quantile fraction and the number of samples that are less than the estimated quantile value.

In another aspect, there is provided apparatus for measuring or correcting loudness of audio content, comprising: an estimated quantile value store, configured to receive an initially estimated quantile value and to maintain a current estimated quantile value; a comparator configured to form comparisons between data values within a fixed-length interval of the said sequence of data values and the current estimated quantile value of the store; a modifier configured to modify the current estimated quantile value of the store in dependence upon a count of the results of said comparisons; and a loudness processing circuit configured to use the modified estimated quantile value in measuring or correcting loudness.

The invention may be embodied in software by the provision of a non-transitory computer program product adapted to cause programmable apparatus to implement a method of measuring loudness in audio content, the method comprising the steps in one or more processors of: receiving a sequence of sample values derived from the audio content, forming an initially estimated quantile value; modifying the initially estimated quantile value in dependence upon a count of the results of comparisons between sample values within a fixed-length interval of the said sequence of samples values and the said initially estimated quantile value to form an estimated quantile of the sequence of sample values; and using the estimated quantile of the sequence of sample values in the measurement of loudness.

### BRIEF DESCRIPTION OF THE DRAWINGS

Examples of the invention will now be described with reference to the drawings in which:

FIG. 1 is a block diagram of a first system for measuring and controlling loudness.

FIG. 2 is a block diagram of a first embodiment of a quantile estimator for use in FIG. 1 or separately;

FIG. 3 is a block diagram of a second embodiment of a quantile estimator;

FIG. 4 is a block diagram of a third embodiment of a quantile estimator;

FIG. 5 is a set of graphs illustrating the performance of the quantile estimator;

FIG. 6 is a block diagram of a second system for measuring and controlling loudness.

### DETAILED DESCRIPTION OF THE INVENTION

Standardised measures for loudness are laid down in a number of international standards including:
1. Recommendation ITU-R BS.1770-4. Describes how to measure loudness, gated loudness and true-peak level over a defined time interval.
2. EBU Recommendation R 128. Loudness normalisation and permitted maximum level of audio signals. Overview document recommending the measurement of programme loudness, loudness range and maximum true peak level, normalisation of loudness and peak limiting.
3. EBU Tech 3341, Loudness Metering: ‘EBU Mode’ metering to supplement loudness normalisation in accordance with EBU R 128. Recommends momentary, short-term and programme loudness measurements and loudness range measurements.

Each of these documents is hereby incorporated by reference

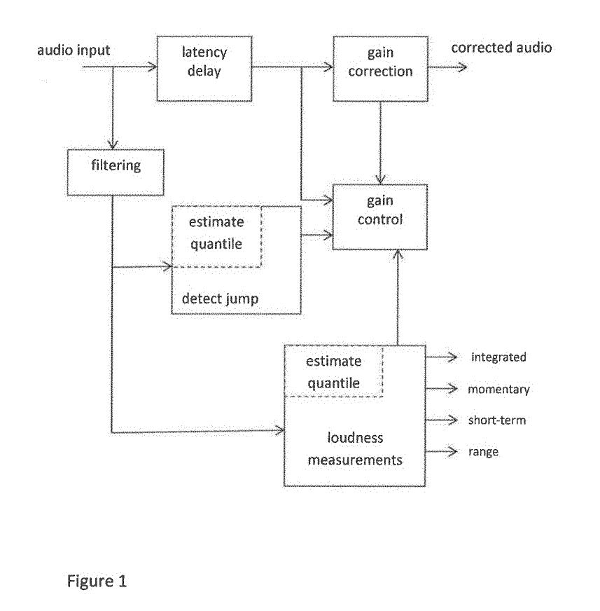

An arrangement for loudness correction and loudness measurement will be described by reference to FIG. 1. It will of course be understood that loudness measurement could be provided separately and that loudness correction could be provided with only such measurement as is necessary for the loudness correction.

The main processing mode is to adjust a gain parameter smoothly (here at 1/10 second intervals known as hops) in order to try to achieve a target relative gated loudness, typically −23 dB (measured across the specified integration period, typically 10 seconds, with the specified look-ahead (latency) period, typically 0.4 seconds) within a specified tolerance, typically +1 dB. If the loudness is not within the limits defined, a current gain value is increased or decreased by a small amount (typically 0.2 dB increase or 1.0 dB decrease) in the right direction, towards a running target gain which is the difference between the target loudness and the integrated loudness.

This is so-called “wideband” correction, where the gain is applied equally across all frequencies in the signal, but frequency dependent correction could also be provided.

It is important to detect jumps in input loudness (for example, at the start of a commercial). If available, a text file can be read in giving the times of any possible jumps. The approach for dealing with known jump times is quite simple: the integrated loudness measurement stops at the jump point, so that for a period equal to the latency before the jump the loudness measurement does not extend past the jump. The measurement is reset at the jump so that we have a new integrated loudness measured over the latency period following the jump. And at the jump, the gain is allowed to change abruptly, up or down, to compensate for the new integrated loudness.

In case such a text file is not available, running estimates of high and low reference loudness values (typically the 95th and 10th centile, ignoring silent periods) are maintained and a jump is declared when the average loudness in the look-ahead period (called the post-jump loudness) is outside these limits by a specified amount (typically 3 dB). A jump down to a loudness that is less than a “quiet threshold” (typically −43 dB) is ignored.

When a jump is detected, a target gain is set to the difference between the target loudness and the post-jump loudness. The gain is allowed to change abruptly towards the target gain; in the case of a jump up in loudness (corrected by a jump down in gain) the gain is changed by the difference between the post-jump loudness and the high reference loudness. In the case of a jump down in loudness (corrected by a jump up in gain), the gain is changed by the difference between the post-jump loudness and the low reference loudness. In both cases the abruptness can be modified by a multiplication factor applied to the change.

The running estimate of the 95th centile (high reference) loudness is maintained, in the estimate quantile function, by subtracting a small value (known as the rolling centile increment or ε,) from the reference loudness whenever the instantaneous loudness is below the reference, otherwise adding 19ε to the reference loudness. As will be explained in more detail below, this works because in the steady state, where the reference loudness is equal to the 95th centile of the distribution, it will be incremented by 19ε once for every 19 times it is decremented by ε. In general, the multiplier of ε for the increment operation is set to (centile/(100−centile)). An equivalent method is used for the 10th centile (low reference) loudness. After a jump, the high or low reference loudness (whichever was used) is reset to the post-jump loudness.

Loudness measurements are provided, for example in accordance with the referenced standards. In providing a loudness range measurement, specified quantiles are used, for example 5% and 95%. These may in appropriate applications also be estimated as described above.

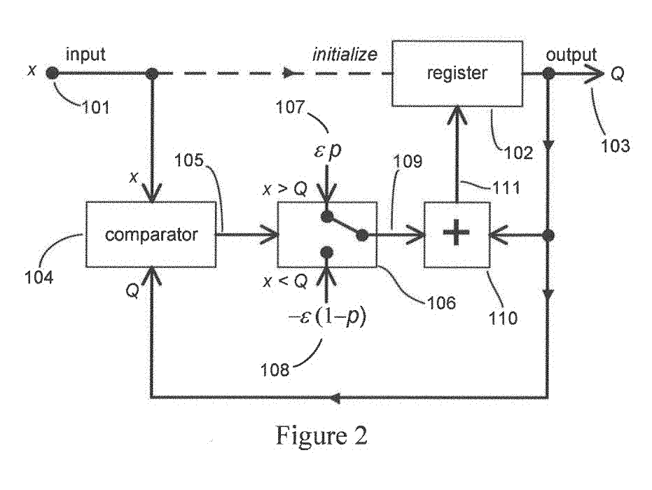

A first embodiment of a quantile estimator will now be described with reference to FIG. 2, which shows a sequential process that receives a sequence of data samples, and outputs a sequence of estimates of a particular quantile of the input data, at a rate of one output estimate per input data sample.

Input data samples x arrive sequentially at the input (101). At the start of the process a register (102) is initialized by loading it with the value of the first input data sample. As the process continues, the register (102) stores a current estimate of the required quantile and passes it to the output Q (103). The register (102) operates at the input data rate and has a delay of one input sample period, that is to say its current output is equal to a valued loaded into it that depends on the previous input data sample.

Each input data sample x (101) is compared with the output Q (103) in a comparator (104). The result (105) of the comparison is used in a data selector (106) to select between two fixed numbers: εp (107) if x>Q; or, −ε(1−p) (108) if x<Q. The selected fixed number (109) is input to an adder (110). The value of p is a constant equal to the desired quantile fraction. Thus when the current input data sample x is greater than the estimate Q, the product of the required quantile fraction p and the constantε is passed to the adder (110); and, when the current input data sample x is less than the estimate Q, the product of the complement of the required quantile fraction p and the constant ε is passed to the adder (110).

ε is a small constant whose value is chosen as a trade-off between smoothness of the output and responsiveness to initial conditions and to changes in the input signal statistics. If the result of the comparison is equality, then zero, or either of the two fixed inputs, may be selected. The output (109) of the data selector is added (110) to the current output Q (103) of the register (102) to form an updated quantile estimate (111), which is loaded into the register (102), and will be output when the next input data sample x (101) arrives.

The reasoning behind the algorithm is as follows: If Q=q, where q is the true value of the desired quantile, then its expected increase will be (1−p)εp and the expected decrease will be pε(1−p), so Q will have no tendency to change in the long term. However, if Q<q, then the expected increase will be greater than (1−p)εp (because it will be applied more often than a proportion (1−p) of the time) and the expected decrease will be less than pε(1−p), so Q will tend to increase towards q. Likewise, if Q>q, then Q will tend to decrease towards q.

Variations to the first embodiment may be applied by the skilled person without departing from the scope of the invention. For example, the initial estimate of the quantile may be set to zero, or to a constant value derived from prior knowledge of the data. The sequence of output quantile estimates Q may also be filtered by a smoothing filter.

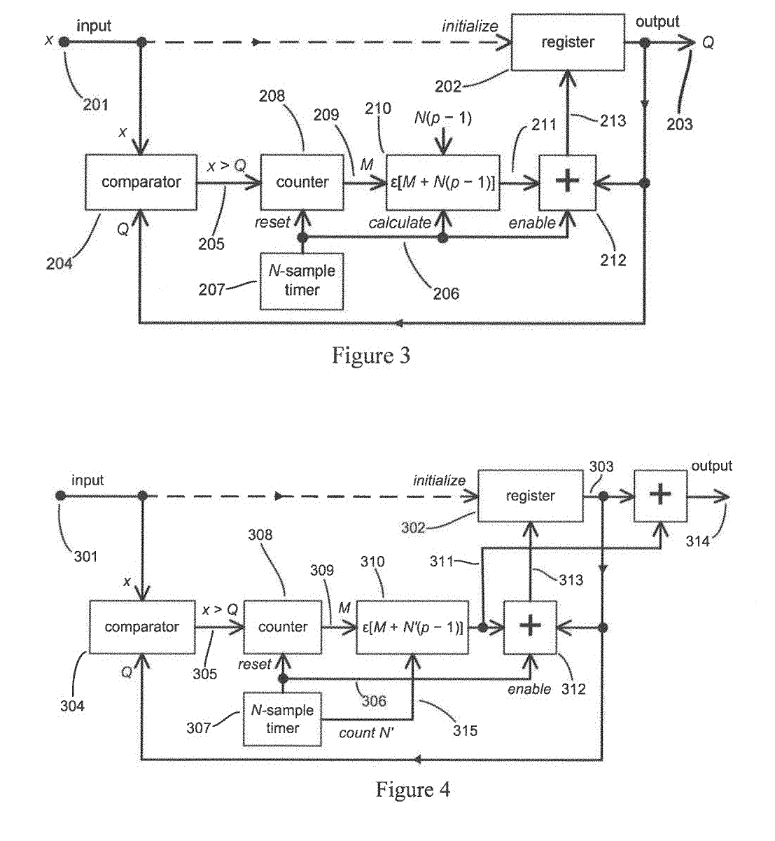

A second embodiment of the invention will now be described, and is illustrated in FIG. 3 in which elements analogous with elements of FIG. 2 have similar designatory numerals with the initial digit 1 replaced by 2. The second embodiment has two advantages over the first embodiment. The first advantage is that it avoids the single-sample-period loop during which the first embodiment must: read from the register; perform a comparison; select between two numbers according to the comparison; perform an addition; and, write the result back into the register. The second advantage is that it improves the tradeoff between smoothness and response time. The second embodiment makes comparisons on every incoming data sample, but only changes the estimate Q at fixed intervals a chosen, set number, of input data samples apart. Supposing for the moment that equality does not occur in the comparisons, the process only needs to keep account of the number of times the input sample x exceeds the held value of Q in the register (202) in order to calculate the change to be made to Q at the end of the interval. For example, if the chosen interval is N data points, and the number of times x exceeds Q is M, then the net increase to be applied to Q at the end of the interval is ε[Mp−(N−M)(1−p)]=ε[M+N(p−1)].

Referring to FIG. 3, the first input data sample x (201) initializes the register (202) that operates in a similar way to the register (102) of the first embodiment, except that it is only loaded with a new quantile estimate every N input samples. Subsequent input data samples pass to a first input to a comparator (204), whose other input is the output Q (203) from the register (202), as in the first embodiment. The output (205) of the comparator (204) drives a counter (208) which increments every time x>Q. The counter is regularly reset to zero by the output (206) of an N-sample timer (207). The regular output from the N-sample timer (207) also enables the calculation (210) of a new value of the quantity ε[M+N(p−1)], where M is the state (209) of the counter (208). The result (211) of the calculation is added (212) to the currently output quantile estimate (203) to produce a new quantile estimate (213), which is written into the register (202), and will be output when the register (202) is next loaded after N input data samples have been received.

Several possible methods exist for handling equality in the comparisons. Firstly, the relative quantization of the input data and of the quantile estimate could be arranged so that equality cannot occur, or occurs very rarely. Secondly, equality could be treated arbitrarily, or, randomly as one of the two other outcomes. Thirdly, two counters could be employed, so that all three outcomes from the comparator could properly be recorded.

A third embodiment of the invention will now be described, and is illustrated in FIG. 4 in which elements analogous to those of FIG. 3 have similar designatory numerals with the initial digit 2 replaced by 3. This embodiment is similar to the second embodiment, except that an out-of-loop correction is added to the final output to improve the response time at the expense of a slight increase in complexity. Referring to FIG. 4, the operation is similar to that shown in FIG. 3 except for the following differences: The calculation unit (310) operates every time an input data sample is received, using the instantaneous count value M (309) and an additional sample-count output N′ (315) from the N-sample timer. The register (302) is loaded with a new quantile estimate (313) at the end of each N-sample segment of the input data stream, in exactly the same way as in the second embodiment. However, the calculated output (311) corresponding to every input data sample is added to the output (303) of the register (302) to produce a final output quantile estimate (314) every time an input data sample is received.

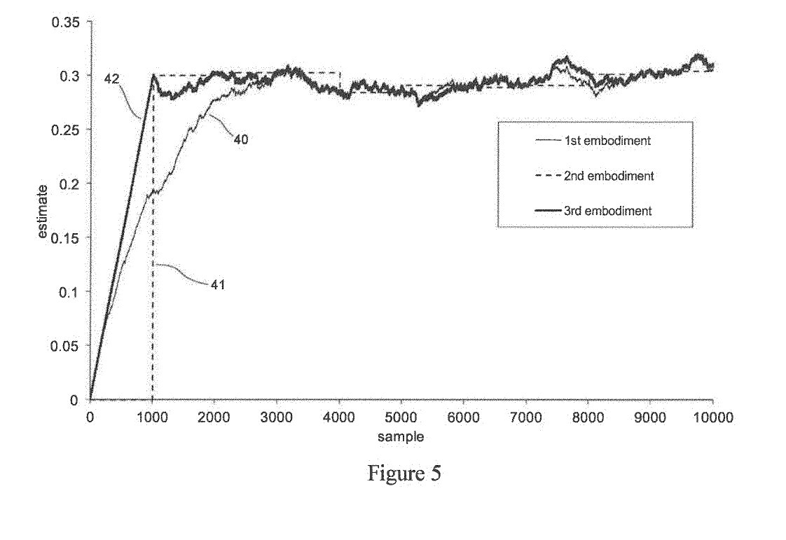

FIG. 5 gives a comparative illustration of the performance of the three embodiments described. In this example, the 30^{th} centile (p=0.3) of the distribution of data uniformly distributed on [0, 1] is being estimated, for which the expected value q is 0.3. The value of εis 1/1000.

The output of the first embodiment, in which Q is updated in the loop at every sample, is shown as a fine line (40). This version takes about 3000 sample periods to converge to an approximately correct value. The output of the second embodiment, in which the estimate is only updated (in this case) every N=1000 samples, is shown as a dotted line (41). It converges to a correct value in 1000 samples. Finally, the output of the third embodiment, in which a sample-rate out-of-loop correction is added at the end, is shown as a thick line (42). This is similar to the first embodiment except that it converges more quickly.

Three exemplary embodiments of the invention have been described in terms of sequential processes operating in inter-connected functional blocks. However, the skilled person will recognise that the described inventive concept can be practiced in many other ways. For example the data sequence may not be a temporal sequence, it may be a spatial sequence, or some other sequence in which a plurality of data values are arranged in an ordered set. The concept of an interval within the set of input values may not be a period of time; an interval is a contiguous set of samples in the ordered set of input samples, and its length is the number of samples that it comprises.

The data samples to be processed may be simultaneously accessible in a file or memory device. The functionality may be implemented in a sequence of instructions for a programmable device.

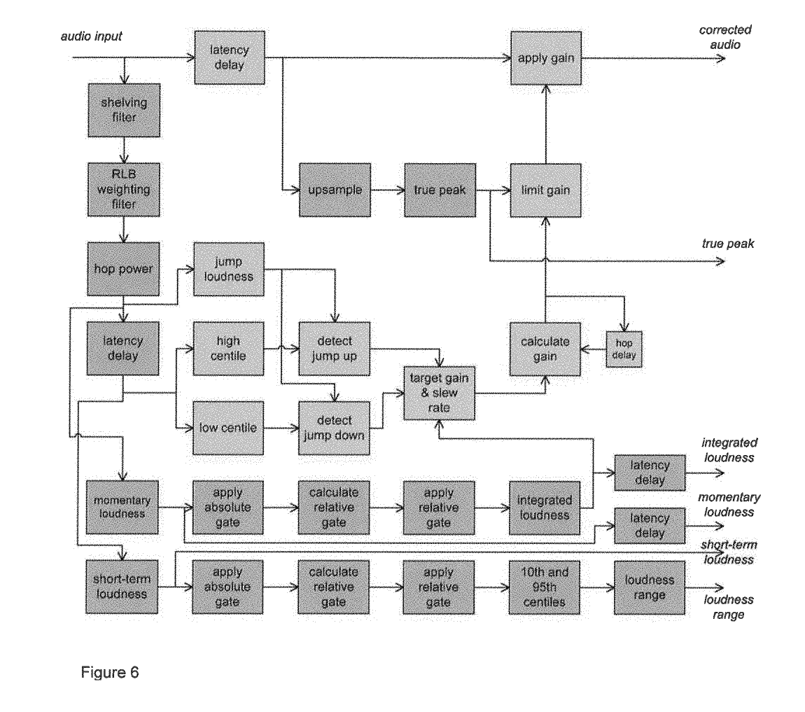

A block diagram of a more complete loudness measurement and correction system is given in FIG. 6.

The functionality of the various blocks in FIG. 6 is as follows:

A Shelving filter compensates for the acoustic effects of the head. This filter is described fully in ITU-R Rec. BS.1770-4. A RLB filter provides the second stage weighting curve, a high pass filter, described fully in ITU-R Rec. BS.1770-4. The Hop power block calculates the mean square value of the filtered signal within each 1/10 second hop. A Latency delay Buffers the filtered signal, allowing the processing to look ahead.

A Momentary loudness block averages the power over 4 hops (0.4 sec) to give a momentary loudness estimate according to EBU Tech 3341.

In the calculation of integrated loudness (penultimate row of blocks), the Apply absolute gate considers only those momentary loudness values that exceed (are louder than) a given level. The Calculate relative gate sets a gate 20 dB (for example) below the loudness corresponding to the average gated momentary loudness, averaged over the integration period in the power domain. This averaging is also performed over the whole file as part of the calculation of an overall integrated loudness value. The Apply relative gate considers only those loudness values that exceed the relative gate value. Then, the Integrated loudness block averages the relative-gated loudness values over the integration period to obtain a rolling estimate of integrated (gated) loudness. This averaging is also performed over the whole file to give an overall integrated loudness value.

In the calculation of loudness range (last row of blocks)the Short-term loudness block averages the power over 30 hops (3 sec) to give a short-term loudness estimate according to EBU Tech 3341. The Apply absolute gate considers only those short-term loudness values that exceed (are louder than) a given level. The Calculate relative gate sets a gate 10 dB below the loudness corresponding to the average gated short-term loudness, averaged over the whole file in the power domain, as part of the calculation of loudness range. The 10th and 95th centiles blocks find the 10th and 95th centile points of the distribution over the whole file of relative-gated short-term loudness values or estimate them as described above. The Loudness range block then outputs the difference between the 95th and 10th centile values.

Loudness processing calculations are performed once per hop.

The Jump loudness block calculates the average loudness (in the power domain) over the latency look-ahead period. This is the loudness value used for detecting if a jump has occurred. The High reference block maintains a running estimate of the 95th centile (high reference) loudness as described above. If a jump up is detected, the high centile is set to the jump loudness. The Low centile block maintains a running estimate of the 10th centile (low reference) loudness values as described above. If a jump down is detected, the low centile is set to the jump loudness. In the Detect jump up block, a jump up is detected if the jump loudness exceeds the high centile loudness by more than a defined amount. In the Detect jump down block a jump down is detected if the jump loudness falls below the low centile loudness by more than a defined amount.

Turning to the Target gain and slew rate block, if a jump is not detected and the integrated loudness is not already between the tolerance values, the target gain is updated to the difference between the target loudness and the integrated loudness, and the slew rate is set to the appropriate slew rate limit. If a jump up is detected, the target gain is set to the difference between the target loudness and the jump loudness and the slew rate is set to the difference between the jump loudness and the high centile loudness, multiplied by a confidence factor. If a jump down is detected, the target gain is set to the difference between the jump loudness and the target loudness, and the slew rate is set to the difference between the jump loudness and the low centile loudness, multiplied by a confidence factor.

The Calculate gain block operates as follows. If the current gain value is less than the target gain, the gain is updated by adding the upward slew rate. If the current gain value is greater than the target gain, the gain is updated by adding the (negative) downward slew rate.

If the true peak value (see below) plus the gain exceeds the true peak limit, the Limit gain block serves to reduce the gain to the difference between the true peak limit and the true peak value. The gain is subsequently limited to fall between the specified maximum and minimum gain values.

In the Apply gain block , the gain (currently expressed in dB) is converted to a multiplicative gain and applied to all the samples in the hop, obtained at the output of a compensating latency delay.

To calculate the true peak, the Upsampleblock upsamples the input signal by 4 using the filters specified in ITU-R Rec. BS.1770-4. The largest sample value in the upsampled hop is found by the True peak block.

It will be understood that this complete system has been described by way of example only and that the estimate quintile function that has been described may be used in other ways in the measurement or correction of audio loudness

1. Apparatus for measuring or correcting loudness of audio content, comprising:
an estimated quantile value store, configured to receive an initially estimated quantile value and to maintain a current estimated quantile value;
a comparator configured to form comparisons between data values within a fixed-length interval of the said sequence of data values and the current estimated quantile value of the store;
a modifier configured to modify the current estimated quantile value of the store in dependence upon a count of the results of said comparisons; and
a loudness processing circuit configured to use the modified estimated quantile value in measuring or correcting loudness.

2. Apparatus according to claim 1 in which the modification is proportional to the difference between:
the product of the quantile fraction and the number of data samples that exceed the current estimated quantile value; and,
the product of the complement of the quantile fraction and the number of data samples that are less than the current estimated quantile value.

3. Apparatus according to claim 2 in which the fixed-length interval is one data value in length.

4. Apparatus according to claim 3 in which, a plurality of fixed-length intervals are analysed and the respective modified estimate for each processed interval is output as a quantile estimate.

5. Apparatus according to claim 4 in which a plurality of fixed-length intervals are analysed and a sequence of quantile estimates is output comprising, for each input data value, the respective sum of the modified quantile estimate from a preceding interval and the instantaneous value of the modification for that data sample.

6. A method of measuring or correcting loudness in audio content, the method comprising the steps in one or more processors of:
receiving a sequence of sample values derived from the audio content,
forming an initially estimated quantile value;
modifying the initially estimated quantile value in dependence upon a count of the results of comparisons between sample values within a fixed-length interval of the said sequence of samples values and the said initially estimated quantile value to form an estimated quantile of the sequence of sample values; and
using the estimated quantile of the sequence of sample values in the measurement or correction of loudness.

7. A method according to claim 6 in which the modification is proportional to the difference between:
the product of the quantile fraction and the number of samples that exceed the estimated quantile value; and
the product of the complement of the quantile fraction and the number of samples that are less than the estimated quantile value.

8. A method according to claim 6 in which the fixed-length interval is one data value in length.

9. A method according to claim 6 in which, a plurality of fixed-length intervals are analysed and the respective modified estimate for each processed interval is output as a quantile estimate.

10. A method according to claim 6 in which a plurality of fixed-length intervals are analysed and a sequence of quantile estimates is output comprising, for each input sample value, the respective sum of the modified quantile estimate from a preceding interval and the instantaneous value of the modification for that sample.

11. A non-transitory computer program product adapted to cause programmable apparatus to implement a method of measuring loudness in audio content, the method comprising the steps in one or more processors of:
receiving a sequence of sample values derived from the audio content,
forming an initially estimated quantile value;
modifying the initially estimated quantile value in dependence upon a count of the results of comparisons between sample values within a fixed-length interval of the said sequence of samples values and the said initially estimated quantile value to form an estimated quantile of the sequence of sample values; and
using the estimated quantile of the sequence of sample values in the measurement of loudness.

12. A non-transitory computer program product according to claim 11 in which the modification is proportional to the difference between:
the product of the quantile fraction and the number of samples that exceed the estimated quantile value; and
the product of the complement of the quantile fraction and the number of samples that are less than the estimated quantile value.

13. A non-transitory computer program product according to claim 12 in which the fixed-length interval is one data value in length.

14. A non-transitory computer program product according to claim 12 in which, a plurality of fixed-length intervals are analysed and the respective modified estimate for each processed interval is output as a quantile estimate.

15. A non-transitory computer program product according to claim 12 in which a plurality of fixed-length intervals are analysed and a sequence of quantile estimates is output comprising, for each input sample value, the respective sum of the modified quantile estimate from a preceding interval and the instantaneous value of the modification for that sample.
